(19) United States
(12) Patent Application Publication
(10) Pub. No.: US 2014/0091393 A1
(43) Pub. Date: Apr. 3, 2014

(54) SEMICONDUCTOR DEVICE, SEMICONDUCTOR WAFER, METHOD FOR PRODUCING SEMICONDUCTOR WAFER, AND METHOD FOR PRODUCING SEMICONDUCTOR DEVICE

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); THE UNIVERSITY OF TOKYO, Tokyo (JP)

(72) Inventors: Masahiko HATA, Tsukuba-shi (JP); Hisashi YAMADA, Tsukuba-shi (JP); Masafumi YOKOYAMA, Bunkyo-ku (JP); SangHyeon Kim, Bunkyo-ku (JP); Mitsuru TAKENAKA, Bunkyo-ku (JP); Shinichi TAKAGI, Bunkyo-ku (JP); Tetsuji YASUDA, Tsukuba-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); THE UNIVERSTIY OF TOKYO, Tokyo (JP)

(21) Appl. No.: 14/099,427

(22) Filed: Dec. 6, 2013

Related U.S. Application Data
(63) Continuation-in-part of application No. PCT/JP2012/003769, filed on Jun. 8, 2012.

(30) Foreign Application Priority Data
Jun. 10, 2011 (JP) 2011-130727

(51) Int. Cl. H01L 27/092; H01L 21/8252; H01L 27/12; H01L 21/762; H01L 21/8238

(52) U.S. Cl. CPC H01L 27/0922; H01L 21/76254; H01L 21/823807; H01L 27/1203; H01L 21/8252
USPC 257/351; 438/458; 438/229

(57) ABSTRACT

There is provided a semiconductor device including: a first source and a first drain of a first-channel-type MISFET formed on a first semiconductor crystal layer, which are made of a compound having an atom constituting the first semiconductor crystal layer and a nickel atom, a compound having an atom constituting the first semiconductor crystal layer and a cobalt atom, or a compound having an atom constituting the first semiconductor crystal layer, a nickel atom, and a cobalt atom; and a second source and a second drain of a second-channel-type MISFET formed on a second semiconductor crystal layer, which are made of a compound having an atom constituting the second semiconductor crystal layer and a nickel atom, a compound having an atom constituting the second semiconductor crystal layer and a cobalt atom, or a compound having an atom constituting the second semiconductor crystal layer, a nickel atom, and a cobalt atom.

The contents of the following patent applications are incorporated herein by reference:
No. 2011-130727 filed in Japan on Jun. 10, 2011, and
No. PCT/JP2012/003769 flied on Jun. 8, 2012.

### BACKGROUND

1. Technical Field

The present invention relates to a semiconductor device, a semiconductor wafer, a method for producing a semiconductor wafer, and a method for producing a semiconductor device. Note that the present application is based on the research “Technical Development on New Material for Nanoelectronics Semiconductor and New-Structure Nanoelectronic Device—Research and Development on Group III-V Semiconductor Channel Transistor Technology on Silicon Platform” of the year 2010 entrusted by the New Energy and Industrial Technology Development Organization (NEDO) and applies to Art. 19 of Industrial Technology Enhancement Act.

2. Related Art

Group III-V compound semiconductors such as GaAs and InGaAs have a high electron mobility, whereas Group IV semiconductors such as Ge and SiGe have a high hole mobility. Therefore, a high-performance CMOSFET (Complementary Metal-Oxide-Semiconductor Field-Effect Transistor) can be realized by using a Group III-V compound semiconductor to make an N-channel-type MOSFET (Metal-Oxide-Semiconductor Field-Effect Transistor) and using a Group IV semiconductor to make a P-channel-type MOSFET. Non-patent Document No. 1 discloses a CMOSFET structure in which an N-channel-type MOSFET whose channel is made of a Group III-V compound semiconductor and a P-channel-type MOSFET whose channel is made of Ge are formed on a single wafer.
Non-patent Document No. 1: S. Takagi, et al., SSE, vol. 51, p. 526-536, 2007

### SUMMARY OF THE INVENTION

### Problems to be Solved by the Invention

So as to form, on a single wafer, an N-cannel-type MISFET (hereinafter simply referred to as “nMISFET”) whose channel is made of a Group III-V compound semiconductor and a P-channel-type MISFET (hereinafter simply referred to as “pMISFET”) whose channel is made of a Group IV semiconductor, there is required a technique to form, on the same wafer, the Group III-V compound semiconductor to be used for the nMISFET and the Group IV semiconductor to be used for the pMISFET. For enabling LSI (Large Scale Integration) production, it is preferable to form a Group III-V compound semiconductor crystal layer to be used for an nMISFET and a Group IV semiconductor crystal layer to be used for a pMISFET on a silicon wafer to which existing production equipment and existing processes are applicable.

So as to inexpensively and efficiently produce as an LSI a CMISFET (Complementary Metal-Insulator-Semiconductor Field-Effect Transistor) made up of an nMISFET and a pMISFET, it is preferable to adopt the production process enabling simultaneous formation of an nMISFET and a pMISFET. Simultaneously forming, in particular, the source/drain of the nMISFET and the source/drain of the pMISFET can simplify the process and easily cope with the need for cost reduction and miniaturization of devices.

The source/drain of the nMISFET and the source/drain of the pMISFET can be simultaneously formed by, for example, forming thin films using materials to become a source and a drain on both of the source/drain formation regions of the nMISFET and the source/drain formation regions of the pMISFET, and then patterning the films by photolithography or the like. The Group III-V compound semiconductor crystal layer from which the nMISFET is formed

is, however, different from the Group IV semiconductor crystal layer from which the pMISFET is formed, in constituent material. This increases a resistance of the source/drain regions of one or both of the nMISFET and the pMISFET, or increases a contact resistance of the source/drain regions of one or both of the nMISFET and the pMISFET with respect to the source/drain electrodes. It is therefore difficult to reduce a resistance of the source/drain regions of both of the nMISFET and the pMISFET, or a contact resistance of the regions with respect to the source/drain electrodes.

An object of the present invention is to provide a semiconductor device and a method for producing the same, which can realize simultaneous formation of each source and each drain of an nMISFET and a pMISFET with a smaller resistance in the source/drain regions or a smaller contact resistance of the regions with the source/drain electrodes, when forming, on a single wafer, a CMISFET made up of an nMISFET whose channel is made of a Group II-V compound semiconductor and a pMISFET whose channel is made of a Group IV semiconductor, and to further provide a semiconductor wafer suitable for such technique.

### Means for Solving the Problems

Given the aforementioned problems, according to the first aspect related to the present invention, there is provided a semiconductor device including: a base wafer, a first semiconductor crystal layer positioned above the base wafer, a second semiconductor crystal layer positioned above a partial area of the first semiconductor crystal layer; a first MISFET having a channel formed in a part of an area of the first semiconductor crystal layer above which the second semiconductor crystal layer does not exist and having a first source and a first drain; and a second MISFET having a channel formed in a part of the second semiconductor crystal layer and having a second source and a second drain, where the first MISFET is a first-channel-type MISFET and the second MISFET is a second-channel-type MISFET, the second-channel-type being different from the first-channel-type, the first source and the first drain are made of a compound having an atom constituting the first semiconductor crystal layer and a nickel atom, a compound having an atom constituting the first semiconductor crystal layer and a cobalt atom, or a compound having an atom constituting the first semiconductor crystal layer, a nickel atom, and a cobalt atom, and the second source and the second drain are made of a compound having an atom constituting the second semiconductor crystal layer and a nickel atom, a compound having an atom constituting the second semiconductor crystal layer and a cobalt atom, or a compound having an atom constituting the second semiconductor crystal layer, a nickel atom, and a cobalt atom.

The semiconductor device may further include: a first separation layer that is positioned between the base wafer and the first semiconductor crystal layer, and electrically separates the base wafer from the first semiconductor crystal layer; and a second separation layer that is positioned between the first semiconductor crystal layer and the second semiconductor crystal layer, and electrically separates the first semiconductor crystal layer from the second semiconductor crystal layer.

The semiconductor device may further include a second separation layer that is positioned between the first semiconductor crystal layer and the second semiconductor crystal layer, and electrically separates the first semiconductor crystal layer from the second semiconductor crystal layer, where the base wafer is in contact with the first semiconductor crystal layer via a bonding plane, impurity atoms exhibiting a p-type or n-type conductivity type are contained in an area of the base wafer in the vicinity of the bonding plane, and impurity atoms exhibiting a conductivity type different from the conductivity type of impurity atoms contained in the base wafer are contained in an area of the first semiconductor crystal layer in the vicinity of the bonding plane.

The base wafer may be in contact with the first separation layer, in which case an area of the base wafer that is in contact with the first separation layer is conductive, and a voltage applied to the area of the base wafer that is in contact with the first separation layer functions as a back gate voltage with respect to the first MISFET. The first semiconductor crystal layer may be in contact with the second separation layer, in which case an area of the first semiconductor crystal layer that is in contact with the second separation layer is conductive, and a voltage applied to the area of the first semiconductor crystal layer that is in contact with the second separation layer functions as a back gate voltage with respect to the second MISFET.

When the first semiconductor crystal layer is made of a Group IV semiconductor crystal, the first MISFET is preferably a P-channel-type MISFET, and when the second semiconductor crystal layer is made of a Group III-V compound semiconductor crystal, the second MISFET is preferably an N-channel-type MISFET. When the first semiconductor crystal layer is made of a Group III-V compound semiconductor crystal, the first MISFET is preferably an N-channel-type MISFET, and when the second semiconductor crystal layer is made of a Group IV semiconductor crystal, the second MISFET is preferably a P-channel-type MISFET.

According to the second aspect related to the present invention, there is provided a semiconductor wafer used for the first aspect, the semiconductor wafer including: the base wafer, the first semiconductor crystal layer, and the second semiconductor crystal layer, where the first semiconductor crystal layer is positioned above the base wafer, and the second semiconductor crystal layer is positioned above a part or all of the first semiconductor crystal layer.

The semiconductor wafer may further include: a first separation layer that is positioned between the base wafer and the first semiconductor crystal layer, and electrically separates the base wafer from the first semiconductor crystal layer; and a second separation layer that is positioned between the first semiconductor crystal layer and the second semiconductor crystal layer, and electrically separates the first semiconductor crystal layer from the second semiconductor crystal layer. In this case, the first separation layer may be made of an amorphous insulator, or a semiconductor crystal having a wider band gap than a band gap of a semiconductor crystal constituting the first semiconductor crystal layer.

The semiconductor wafer may further include a second separation layer that is positioned between the first semiconductor crystal layer and the second semiconductor crystal layer, and electrically separates the first semiconductor crystal layer from the second semiconductor crystal layer, where the base wafer is in contact with the first semiconductor crystal layer via a bonding plane, impurity atoms exhibiting a p-type or n-type conductivity type are contained in an area of the base wafer in the vicinity of the bonding plane, and impurity atoms exhibiting a conductivity type different from the conductivity type of impurity atoms contained in the base wafer are contained in an area of the first semiconductor crystal layer in the vicinity of the bonding plane.

The second separation layer may be made of an amorphous insulator, or a semiconductor crystal having a wider band gap than a band gap of a semiconductor crystal constituting the second semiconductor crystal layer. The semiconductor wafer may include a plurality of the second semiconductor crystal layers, where each of the plurality of second semiconductor crystal layers is arranged regularly within a plane parallel to an upper plane of the base wafer.

According to the third aspect related to the present invention, there is provided a method for producing the semiconductor wafer, the method including first semiconductor crystal layer forming of forming the first semiconductor crystal layer above the base wafer, and second semiconductor crystal layer forming of forming the second semiconductor crystal layer above a partial area of the first semiconductor crystal layer, where the second semiconductor crystal layer forming includes: epitaxial growth of forming the second semiconductor crystal layer on a semiconductor crystal layer forming wafer by epitaxial growth; forming, on the first semiconductor crystal layer, on the second semiconductor crystal layer, or on both of the first semiconductor crystal layer and the second semiconductor crystal layer, a second separation layer that electrically separates the first semiconductor crystal layer from the second semiconductor crystal layer; and bonding the base wafer including the first semiconductor crystal layer to the semiconductor crystal layer forming wafer so that the second separation layer positioned on the first semiconductor crystal layer will be bonded to the second semiconductor crystal layer, that the second separation layer positioned on the second semiconductor crystal layer will be bonded to the first semiconductor crystal layer, or that the second separation layer positioned on the first semiconductor crystal layer will be bonded to the second separation layer positioned on the second semiconductor crystal layer.

The method may be such that the first semiconductor crystal layer forming includes: epitaxial growth of forming the first semiconductor crystal layer on a semiconductor crystal layer forming wafer by epitaxial growth; forming, on the base wafer, on the first semiconductor crystal layer, or on both of the base wafer and the first semiconductor crystal layer, a first separation layer that electrically separates the base wafer from the first semiconductor crystal layer; and bonding the base wafer to the semiconductor crystal layer farming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

When the first semiconductor crystal layer is made of SiGe, and the second semiconductor crystal layer is made of a Group III-V compound semiconductor crystal, the method may include, prior to the first semiconductor crystal layer forming, forming a first separation layer made of an insulator on the base wafer, and the first semiconductor crystal layer forming may include: forming a SiGe layer, which serves as a starting material of the first semiconductor crystal layer, on the first separation layer; and enhancing the concentration of Ge atom in the SiGe layer by heating the SiGe layer in an oxidizing atmosphere to oxidize a surface.

When the first semiconductor crystal layer is made of a Group IV semiconductor crystal, and the second semiconductor crystal layer is made of a Group III-V compound semiconductor crystal, the method may include: forming a first separation layer made of an insulator on a surface of a semiconductor layer material wafer made of a Group IV semiconductor crystal; injecting, via the first separation layer, cations to a predetermined separation depth of the semiconductor layer material wafer, bonding the semiconductor layer material wafer to the base wafer, so that a surface of the first separation layer will be bonded to a surface of the base wafer, degenerating the Group IV semiconductor crystal positioned at the predetermined separation depth by heating the semiconductor layer material wafer and the base wafer, and reacting the cations having been injected to the predetermined separation depth and Group IV atoms constituting the semiconductor layer material wafer, and separating the semiconductor layer material wafer from the base wafer, thereby detaching, from the semiconductor layer material wafer, the portion of the Group IV semiconductor crystal positioned between the base wafer and the portion of the Group IV semiconductor crystal having been degenerated.

The method may include: prior to the first semiconductor crystal layer forming, forming, on the base wafer, a first separation layer made of a semiconductor crystal having a wider band gap than a band gap of a semiconductor crystal constituting the first semiconductor crystal layer by epitaxial growth, where the first semiconductor crystal layer forming is forming the first semiconductor crystal layer on the first separation layer by epitaxial growth.

The first semiconductor crystal layer forming may be forming the first semiconductor crystal layer on the base wafer by epitaxial growth. In this case, impurity atoms exhibiting a p-type or n-type conductivity type may be contained in the vicinity of a surface of the base wafer, and in the forming of the first semiconductor crystal layer by epitaxial growth, the first semiconductor crystal layer may be doped with impurity atoms exhibiting a conductivity type different from a conductivity type of impurity atoms contained in the base wafer.

According to the fourth aspect related to the present invention, there is provided a method for producing a semiconductor wafer of the second aspect, the method including second semiconductor crystal layer forming of forming the second semiconductor crystal layer on a semiconductor crystal layer forming wafer by epitaxial growth; second separation layer forming of forming, on the second semiconductor crystal layer, a second separation layer made of a semiconductor crystal having a wider band gap than a band gap of a semiconductor crystal constituting the second semiconductor crystal layer by epitaxial growth; first semiconductor crystal layer forming of forming the first semiconductor crystal layer on the second separation layer by epitaxial growth; forming, on the base wafer, on the first semiconductor crystal layer, or on both of the base wafer and the first semiconductor crystal layer, a first separation layer that electrically separates the bee wafer from the first semiconductor crystal lay; and bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

The respective method for producing a semiconductor wafer according to the above-described third and fourth aspects related to the present invention, may include, prior to forming a semiconductor crystal layer on the semiconductor crystal layer forming wafer, forming a crystalline sacrificial layer on a surface of the semiconductor crystal layer forming wafer by epitaxial growth; and separating the semiconductor crystal layer forming wafer from the semiconductor crystal layer having been formed by epitaxial growth on the semiconductor crystal layer forming wafer, by removing the crystalline sacrificial layer, after bonding the base wafer to the semiconductor crystal layer forming wafer. The method may include any one of patterning the second semiconductor crystal layers in a regular alignment after having formed the second semiconductor crystal layers by epitaxial growth, or forming the second semiconductor crystal layers in a regular alignment by selective epitaxial growth.

According to the fifth aspect related to the present invention, there is provided a method for producing a semiconductor device, the method including: producing a semiconductor wafer including the first semiconductor crystal layer and the second semiconductor crystal layer by using the method according to the fourth aspect for producing the semiconductor wafer, forming a gate electrode above each of the first semiconductor crystal layer and the second semiconductor crystal layer, with a gate insulating layer therebetween; forming a metal film selected from the group consisting of a nickel film, a cobalt film, and a nickel/cobalt alloy film, on a source electrode forming region of the first semiconductor crystal layer, on a drain electrode forming region of the first semiconductor crystal layer, on a source electrode forming region of the second semiconductor crystal layer, and on a drain electrode forming region of the second semiconductor crystal layer; heating the meal film, thereby forming, in the first semiconductor crystal layer, a first source and a first drain made of a compound having an atom constituting the first semiconductor crystal layer and a nickel atom, a compound having an atom constituting the first semiconductor crystal layer and a cobalt atom, or a compound having an atom constituting the first semiconductor crystal layer, a nickel atom, and a cobalt atom, and forming, in the second semiconductor crystal layer, a second source and a second drain made of a compound having an atom constituting the second semiconductor crystal layer and a nickel atom, a compound having an atom constituting the second semiconductor crystal layer and a cobalt atom, or a compound having at atom constituting the second semiconductor crystal layer, a nickel atom, and a cobalt atom, and removing a non-reacted portion of the metal film.

The summary clause does not necessarily describe all necessary features of the embodiments of the present invention. The present invention may also be a sub-combination of the features described above.

### BRIEF DESCRIPTION OF THE DRAWINGS

FIG. 1 shows a cross section of a semiconductor device 100.

FIG. 2 shows a cross section of the semiconductor device 100 in a production process.

FIG. 3 shows a cross section of the semiconductor device 100 in a production process.

FIG. 4 shows a cross section of the semiconductor device 100 in a production process.

FIG. 5 shows a cross section of the semiconductor device 100 in a production process.

FIG. 6 shows a cross section of the semiconductor device 100 in a production process.

FIG. 7 shows a cross section of the semiconductor device 100 in a production process.

FIG. 8 shows a cross section of the semiconductor device 100 in a production process.

FIG. 9 shows a cross section of a different semiconductor device in a production process.

FIG. 10 shows a cross section of a different semiconductor device in a production process.

FIG. 11 shows a cross section of a different semiconductor device in a production process.

FIG. 12 shows a cross section of a still different semiconductor device in a production process.

FIG. 13 shows a cross section of a still different semiconductor device in a production process.

FIG. 14 shows a cross section of a semiconductor device 200.

### MODE FOR CARRYING OUT THE INVENTION

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

FIG. 1 shows a cross section of a semiconductor device 100. The semiconductor device 100 includes a base wafer 102, a first semiconductor crystal layer 104, and a second semiconductor crystal layer 106. The semiconductor device 100 according to this example includes a first separation layer 108 that is positioned between the base wafer 102 and the first semiconductor crystal layer 104, and a second separation layer 110 that is positioned between the first semiconductor crystal layer 104 and the second semiconductor crystal layer 106. The semiconductor device 100 according to this example includes an insulating layer 112 above the second semiconductor crystal layer 106. Note that from the embodiment example illustrated in FIG. 1, at least two inventions can be interpreted; one invention directed to a semiconductor wafer including, as constituting elements, a base wafer 102, a first semiconductor crystal layer 104, and a second semiconductor crystal layer 106, and another invention directed to a semiconductor wafer including, as constituting elements, a base wafer 102, a first separation layer 108, a first semiconductor crystal layer 104, a second separation layer 110, and a second semiconductor crystal layer 106. A first MISFET 120 is formed on the first semiconductor crystal layer 104, and a second MISFET 130 is formed on the second semiconductor crystal layer 106.

An example of the base wafer 102 includes a wafer whose sure is made of silicon crystals. Examples of the wafer whose surface is made of silicon crystals include a silicon wafer and an SOI (Silicon on Insulator) wafer. A silicon wafer is preferable. Using as the base wafer 102a wafer whose surface is made of silicon crystals enables the utilization of existing production equipment and existing production processes, and can improve the efficiency in R&D and production. The base wafer 102 may also be an insulating wafer such as glass, ceramics, and plastic, a conductive wafer such as metal, or a semiconductor wafer such as silicon carbide, and is not limited to the wafer whose surface is made of silicon crystals.

The first semiconductor crystal layer 104 is provided above the base wafer 102. The first semiconductor crystal layer 104 is made of a Group IV semiconductor crystal or a Group III-V compound semiconductor crystal. The thickness of the first semiconductor crystal layer 104 is preferably equal to or smaller than 20 nm. By making the first semiconductor crystal layer 104 to have the thickness of equal to or smaller than 20 nm, the first MISFET 120 will have an extremely thin film body. By making the body of the first MISFET 120 to be an extremely thin film, the short channel effect can be restrained, and the leak current of the first MISFET 120 can be reduced.

The second semiconductor crystal layer 106 is positioned above a part of the surface of the first semiconductor crystal layer 104. In other words, the second semiconductor crystal layer 106 is positioned above a part of the surface of the first semiconductor crystal layer 104, and a portion of the region of the first semiconductor crystal layer 104 on which no second semiconductor crystal layer 106 exists will function as a channel of the first MISFET 120. The second semiconductor crystal layer 106 is made of a Group III-V compound semiconductor crystal or a Group IV semiconductor crystal. The thickness of the second semiconductor crystal layer 106 is preferably equal to or smaller than 20 nm. By making the second semiconductor crystal layer 106 to have the thickness of equal to or smaller than 20 nm, the second MISFET 130 will have an extremely thin film body. By making the body of the second MISFET 130 to be an extremely thin film, the short channel effect can be restrained, and the leak current of the second MISFET 130 can be reduced.

The electronic mobility is high in the Group III-V compound semiconductor crystal and the hole mobility is high in the Group IV semiconductor crystal, especially in Ge, and therefore it is preferable to form an N-channel-type MISFET in the Group III-V compound semiconductor crystal layer, and form a P-channel-type MISFET in the Group IV semiconductor crystal layer. In other words, when the first semiconductor crystal layer 104 is made of a Group IV semiconductor crystal, and the second semiconductor crystal layer 106 is made of a Group III-IV compound semiconductor crystal, it is preferable to form the first MISFET 120 to be the P-channel-type MISFET, and the second MISFET 130 to be the N-channel-type MISFET.

Conversely, when the first semiconductor crystal layer 104 is made of a Group III-V compound semiconductor crystal, and the second semiconductor crystal layer 106 is made of a Group IV semiconductor crystal, it is preferable to fan a first MISFET 120 to be an N-channel-type MISFET, and a second MISFET 130 to be a P-channel-type MISFET. By doing so, the performance of each of the first MISFET 120 and the second MISFET 130 can be enhanced, and the performance of the CMISFET made of the first MISFET 120 and the second MISFET 130 can be maximized.

Examples of the Group IV semiconductor crystal include a (e crystal and a SiₓGe₁₋ₓ (0≦x<1) crystal. When the Group IV semiconductor crystal is the SiₓGe₁₋ₓ crystal, x is preferably equal to or smaller than 0.10. Examples of the Group III-V compound semiconductor crystal include an InₓGa₁₋ₓAs (0<x<1) crystal, an InAs crystal, a GaAs crystal, and an InP crystal. Another example of the Group III-V compound semiconductor crystal includes a mixed crystal of a Group III-V compound semiconductor that lattice-matches or pseudo-lattice-matches GaAs or InP. A still different example of the Group III-V compound semiconductor crystal includes a laminate of the mixed crystal mentioned above and an InₓGa₁₋ₓAs (0<x<1) crystal, a InAs crystal, a GaAs crystal, or an InP crystal. Note that preferable Group III-V compound semiconductor crystals are an InₓGa₁₋ₓAs (0<x<1) crystal and an InAs crystal, of which an InAs crystal is more preferable.

The first separation layer 108 is positioned between the base wafer 102 and the first semiconductor crystal layer 104. The first separation layer 108 electrically separates the base wafer 102 from the first semiconductor crystal layer 104.

The first separation layer 108 may be made of an amorphous insulator. When forming the first semiconductor crystal layer 104 and the first separation layer 108 by a wafer bonding method, an oxidation condense method, or a smart cut method, the first separation layer 108 will be made of an amorphous insulator. Examples of the first separation layer 108 made of an amorphous insulator include a layer made of at least one of Al₂O₃, AlN, Ta₂O₅, ZrO, HfO₂, La₂O₃, SiOₓ (e.g., SiO₂), SiNₓ (e.g., Si₃N₄) and SiOₓN_{y}, or a laminate of at least two layers selected from among them.

The first separation layer 108 may be made of a semiconductor crystal having a wider bend gap than the band gap of the semiconductor crystal constituting the first semiconductor crystal layer 104. Such semiconductor crystal can be formed by an epitaxial growth method. When the first semiconductor crystal layer 104 is an InGaAs crystal layer or a GaAs crystal layer, examples of the semiconductor crystal constituting the first separation layer 108 include an AlGaAs crystal, an AlInGaP crystal, an AlGaInAs crystal, and an InP crystal. When the first semiconductor crystal layer 104 is a Ge crystal layer, examples of the semiconductor crystal constituting the first separation layer 108 include a SiGe crystal, a Si crystal, a SiC crystal, and a C crystal.

The second separation layer 110 is positioned between the first semiconductor crystal layer 104 and the second semiconductor crystal layer 106. The second separation layer 110 electrically separates the first semiconductor crystal layer 104 from the second semiconductor crystal layer 106.

The second separation layer 110 may be made of an amorphous insulator. When forming the second semiconductor crystal layer 106 and the second separation layer 110 by a wafer bonding method, the second separation layer 110 will be an amorphous insulator. Examples of the second separation layer 110 made of an amorphous insulator include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The second separation layer 110 may be made of a semiconductor crystal having a wider band gap than the band gap of the semiconductor crystal constituting the second semiconductor crystal layer 106. Such semiconductor crystal can be formed by an epitaxial growth method. When the second semiconductor crystal layer 106 is an InGaAs crystal layer or a GaAs crystal layer, examples of the semiconductor crystal constituting the second separation layer 110 include an AlGaAs crystal, an AlInGaP crystal, an AlGaInAs crystal, and an InP crystal. When the second semiconductor crystal layer 106 is a Ge crystal layer, examples of the semiconductor crystal constituting the second separation layer 110 include a SiGe crystal, a Si crystal, a SiC crystal, and a C crystal.

The insulating layer 112 functions as a gate insulating layer of the second MISFET 130. Examples of the insulating layer 112 include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The first MISFET 120 includes a first gate 122, a first source 124, and a first drain 126. The first source 124 and the first drain 126 are formed on the first semiconductor crystal layer 104. The first MISFET 120 is formed on the region of the first semiconductor crystal layer 104 above which no second semiconductor crystal layer 106 is positioned, and uses, as a channel, a part 104a of the first semiconductor crystal layer 104 sandwiched between the first source 124 and the first drain 126. The first gate 122 is provided above this part 104a. A part 110a of the second separating layer 110 is formed on the region sandwiched between the part 104a of the first semiconductor crystal layer 104 being the channel region and the first gate 122. This pert 110a may also function as a gate insulating layer of the first MISFET 120.

The first source 124 and the first drain 126 are made of a compound having an atom constituting the first semiconductor crystal layer 104 and a nickel atom. Alternatively, the first source 124 and the first drain 126 are made of a compound having an atom constituting the first semiconductor crystal layer 104 and a cobalt atom. Still alternatively, the first source 124 and the first drain 126 are made of a compound having an atom constituting the first semiconductor crystal layer 104, a nickel atom and a cobalt atom. A nickel compound, a cobalt compound, or a nickel-cobalt compound constituting the first semiconductor crystal layer 104 is a low-resistance compound having a lower electric resistance.

The second MISFET 130 includes a second gate 132, a second source 134, and a second drain 136. The second source 134 and the second drain 136 are formed in the second semiconductor crystal layer 106. The second MISFET 130 uses, as a channel, a part 106a of the second semiconductor crystal layer 106 sandwiched between the second source 134 and the second drain 136. The second gate 132 is provided above this part 106a. A part 112a of the insulating layer 112 is formed on the region sandwiched between the part 106a of the second semiconductor crystal layer 106 being the channel region and the second gate 132. This part 112a may also function a gate insulating layer of the second MISFET 130.

The second source 134 and the second drain 136 are made of a compound having an atom constituting the second semiconductor crystal layer 106 and a nickel atom. Alternatively, the second source 134 and the second drain 136 are made of a compound having an atom constituting the second semiconductor crystal layer 106 and a cobalt atom. Still alternatively, the second source 134 and the second drain 136 are made of a compound having an atom constituting the second semiconductor crystal layer 106, a nickel atom and a cobalt atom. The nickel compound, the cobalt compound, or the nickel-cobalt compound constituting the second semiconductor crystal layer 106 is a low-resistance compound having a lower electric resistance.

As stated above, the source/drain of the first MISFET 120 (namely, the first source 124 and the first drain 126) and the source/drain of the second MISFET 130 (namely, the second source 134 and the second drain 136) arm made of a compound of common atom(s) (i.e. nickel atom, cobalt atom, or both of these atoms). This configuration enables production of the portion using a material film having common atoms, which helps simplify the production process. In addition, by using nickel, cobalt, or both of than a common atom(s) the electric resistance for the source region and the drain region can be reduced in any of the source/drain formed in a Group III-V compound semiconductor crystal layer and the source/drain formed in a Group IV compound crystal layer. Consequently, it becomes possible to simplify the production process and enhance the performance of the FET.

When the first MISFET 120 is a P-channel-type MISFET and the second MISFET 130 is an N-channel-type MISFET, the first source 124 and the first drain 126 may further contain acceptor impurity atoms, and the second source 134 and the second drain 136 may further contain donor impurity atoms. When the first MISFET 120 is an N-channel-type MISFET and the second MISFET 130 is a P-channel-type MISFET, the first source 124 and the first drain 126 may further contain donor impurity atoms, and the second source 134 and the second drain 136 may further contain acceptor impurity atoms. Examples of the donor impurity atom contained in the source/drain of the N-channel-type MISFET include Si, S, Se and Ge. Examples of the acceptor impurity atom contained in the source/drain of the P-channel-type MISFET include B, Al, Ga and In.

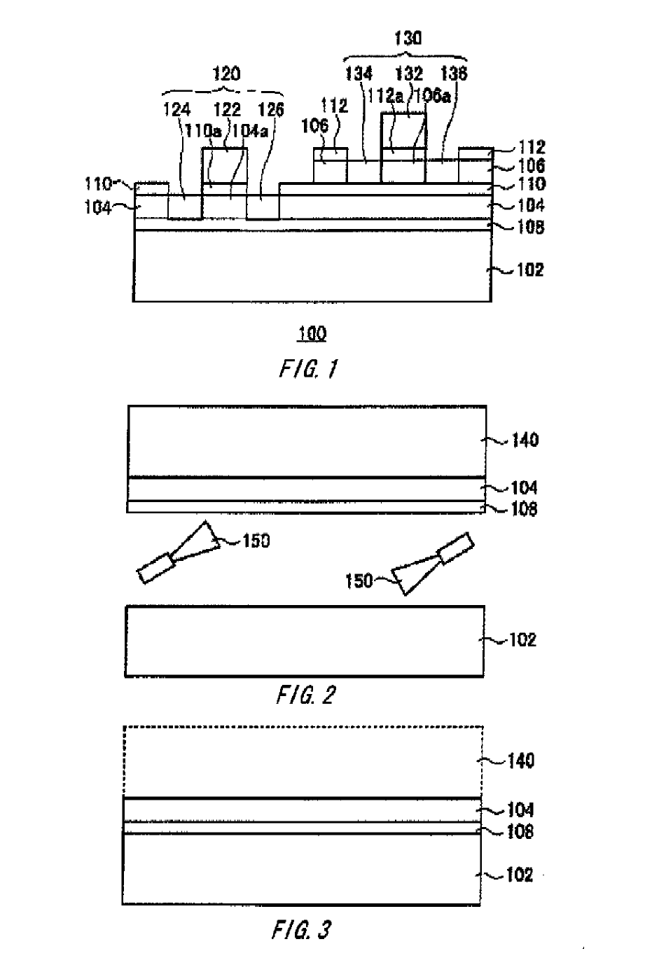

FIG. 2 through FIG. 8 show a cross section of the semiconductor device 100 in a production process. First, a base wafer 102 and a semiconductor crystal layer forming wafer 140 are prepared, and a first semiconductor crystal layer 104 is formed on the semiconductor crystal layer forming wafer 140 by epitaxial growth. Subsequently, a first separation layer 108 is formed on the first semiconductor crystal layer 104. The first separation layer 108 is formed by a thin-film fabrication method such as ALD (Atomic Layer Deposition), thermal oxidation, evaporation, CVD (Chemical Vapor Deposition), and sputtering.

When forming the first semiconductor crystal layer 104 made of a Group m-V compound semiconductor crystal, an InP wafer or a GaAs wafer can be selected as the semiconductor crystal layer forming wafer 140. When forming the first semiconductor crystal layer 104 made of a Group IV semiconductor crystal, a Ge wafer, a Si wafer, a SIC wafer, or a GaAs wafer can be selected as the semiconductor crystal layer forming wafer 140.

MOCVD (Metal Organic Chemical Vapor Deposition) may be used for the epitaxial growth of the first semiconductor crystal layer 104. When forming the Group III-V compound semiconductor crystal layer with the MOCVD method, TMIn (trimethylindium) can be used for an In source, TMGa (trimethylgallium) as a Ga source, AsH₃ (arsine) as an As source, and PH₃ (phosphine) as a P source. Hydrogen can be used as a carrier gas. The reaction temperature can be appropriately adjusted in the range of 300° C. to 900° C., preferably in the range of 450° C. to 750° C. When forming the Group IV compound semiconductor crystal layer with the CVD method, GeH₄ (germane) can be used for a Ge source, and SiN₄ (silane) or Si₂H₆ (disilane) can be used for a Si source. It is also possible to use respective compounds in which a part of the plurality of hydrogen atoms thereof is replaced by a chlorine atom or a hydrocarbon group. Hydrogen can be used as a carrier gas. The reaction temperature can be appropriately adjusted in the range of 300° C. to 900° C., preferably in the range of 450° C. to 750° C. By appropriately adjusting the amount of source gas supply and the reaction time, thickness of the epitaxial growth layer can be controlled.

As shown in FIG. 2, the surface of the first separation layer 108 and the surface of the base wafer 102 are activated using an argon beam 150. Subsequently, as shown in FIG. 3, the surface of the first separation layer 108 and the surface of the base wafer 102, which have been subjected to the argon beam 150 activation, are bonded to each other. The bonding process can be employed in the room temperature. Note that the activation may be employed using a beam of a different rare gas or the like, and is not necessary limited to the argon beam 150. Subsequently, the semiconductor crystal layer forming wafer 140 is etched away. The first separation layer 108 and the first semiconductor crystal layer 104 are resultantly formed on the base wafer 102. Note that, between the formation of the first semiconductor crystal layer 104 and the formation of the first separation layer 108, sulfur termination may be employed to terminate the surface of the first semiconductor crystal layer 104 using sulfur atoms.

While the first separation layer 108 is formed only on the first semiconductor crystal layer 104, and the surface of the first separation layer 108 is bonded to the surface of the base wafer 102 in the examples shown in FIG. 2 and FIG. 3, the first separation layer 108 may also be formed on the base wafer 102, and the surface of the first separation layer 108 which is provided on the first semiconductor crystal layer 104 may be bonded to the surface of the first separation layer 108 which is provided on the base wafer 102. In such a case, it is preferable to subject, to a hydrophilic treatment the surfaces of the first separation layers 108 to be bonded. When having employed the hydrophilic treatment, it is preferable to heat and bond the first separation layers 108 to each other. It is alternatively possible to form the first separation layer 108 only on the base wafer 102, and then bond the surface of the first semiconductor crystal layer 104 to the surface of the first separation layer 108 which is provided on the base wafer 102.

While the first separation layer 108 and the first semiconductor crystal layer 104 are bonded to the base wafer 102 and then separated from the semiconductor crystal layer forming wafer 140 in the examples shown in FIG. 2 and FIG. 3, the first separation layer 108 and the first semiconductor crystal layer 104 may be separated from the semiconductor crystal layer forming wafer 140, and then bonded to the base wafer 102. In the latter case, it is preferable to retain the first separation layer 108 and the first semiconductor crystal layer 104 on an adequate transfer wafer during a period after the first separation layer 108 and the first semiconductor crystal layer 104 are separated from the semiconductor crystal layer forming wafer 140 and until they are bonded to the base wafer 102.

Subsequently, the semiconductor crystal layer forming wafer 160 is prepared, and a second semiconductor crystal layer 106 is formed on the semiconductor crystal layer forming wafer 160 by epitaxial growth. In addition, a second separation layer 110 is formed on the first semiconductor crystal layer 104 provided on the base wafer 102. The second separation layer 110 is formed by a thin-film fabrication method such as ALD, thermal oxidation, evaporation, CVD, and sputtering. Note that, prior to the formation of the second separation layer 110, sulfur termination may be employed to terminate the surface of the first semiconductor crystal layer 104 using sulfur atoms.

When forming the second semiconductor crystal layer 106 made of a Group III-V compound semiconductor crystal, an InP wafer or a GaAs wafer can be selected as the semiconductor crystal layer forming wafer 160. When forming the second semiconductor crystal layer 106 made of a Group IV semiconductor crystal, a Ge wafer, a Si wafer, a SiC wafer, or a GaAs wafer can be selected as the semiconductor crystal layer forming wafer 160.

MOCVD (Metal Organic Chemical Vapor Deposition) can be used for the epitaxial growth of the second semiconductor crystal layer 106. The conditions such as gas or reaction temperature used in the MOCVD am the same as those adopted in the case of the first semiconductor crystal layer 104.

As shown in FIG. 4, the surface of the second semiconductor crystal layer 106 and the surface of the second separation layer 110 are activated using an argon beam 150. Subsequently, as shown in FIG. 5, the surface of the second semiconductor crystal layer 106 is bonded to a part of the surface of the second separation layer 110. The bonding process can be employed in the mom temperature. The activation may be employed using a beam of a different rare gas or the like, and is not necessary limited to the argon beam 150. Subsequently, the semiconductor crystal layer forming wafer 160 is etched away using an HCl solution or the like. The second separation layer 110 is resultantly formed on the first semiconductor crystal layer 104 provided on the base wafer 102, and the second semiconductor crystal layer 106 is resultantly farmed an a part of the surface of the second separation layer 110. Note that, prior to the bonding process between the second separation layer 110 and the first semiconductor crystal layer 104, sulfur termination may be employed to terminate the surface of the second semiconductor crystal layer 106 using sulfur atoms.

While the second separation layer 110 is formed only on the first semiconductor crystal layer 104, and the surface of the second separation layer 110 is bonded to the surface of the second semiconductor crystal layer 106 in the example shown in FIG. 4, the second separation layer 110 may also be formed on the second semiconductor crystal layer 106, and the surface of the second separation layer 110 which is provided on the first semiconductor crystal layer 104 may be bonded to the surface of the second separation layer 110 which is provided on the second semiconductor crystal layer 106. In such a case, it is preferable to subject, to a hydrophilic treatment, the surfaces of the second separation layers 110 to be bonded. When having employed the hydrophilic treatment, it is preferable to heat and bond the second separation layers 110 with each other. It is alternatively possible to form the second separation layer 110 only on the second semiconductor crystal layer 106, and then bond the surface of the first semiconductor crystal layer 104 to the surface of the second separation layer 110 which is provided on the second semiconductor crystal layer 106.

While the second separation layer 106 is bonded to the second separation layer 110 provided on the base wafer 102 and then separated from the semiconductor crystal layer forming wafer 160 in the example shown in FIG. 4, the second semiconductor crystal layer 106 may be separated from the semiconductor crystal layer forming wafer 160, and then bonded to the second separation layer 110. In the latter case, it is preferable to retain the second semiconductor crystal layer 106 on an adequate transfer wafer, during a period after the second semiconductor crystal layer 106 is separated from the semiconductor crystal layer forming wafer 160 and until it is bonded to the second separation layer 110.

Next, as shown in FIG. 6, an insulating layer 112 is formed on the second semiconductor crystal layer 106. The insulating layer 112 is formed by a thin-film fabrication method such as ALD, thermal oxidation, evaporation, CVD, and sputtering. Further, a thin film of a metal, such as tantalum, which is to be a gate, is formed by evaporation, CVD or sputtering, and the thin film is patterned using photolithography, and a first gate 122 is formed above the first semiconductor crystal layer 104 on which no second semiconductor crystal layer 106 is formed, and a second gate 132 is formed above the second semiconductor crystal layer 106.

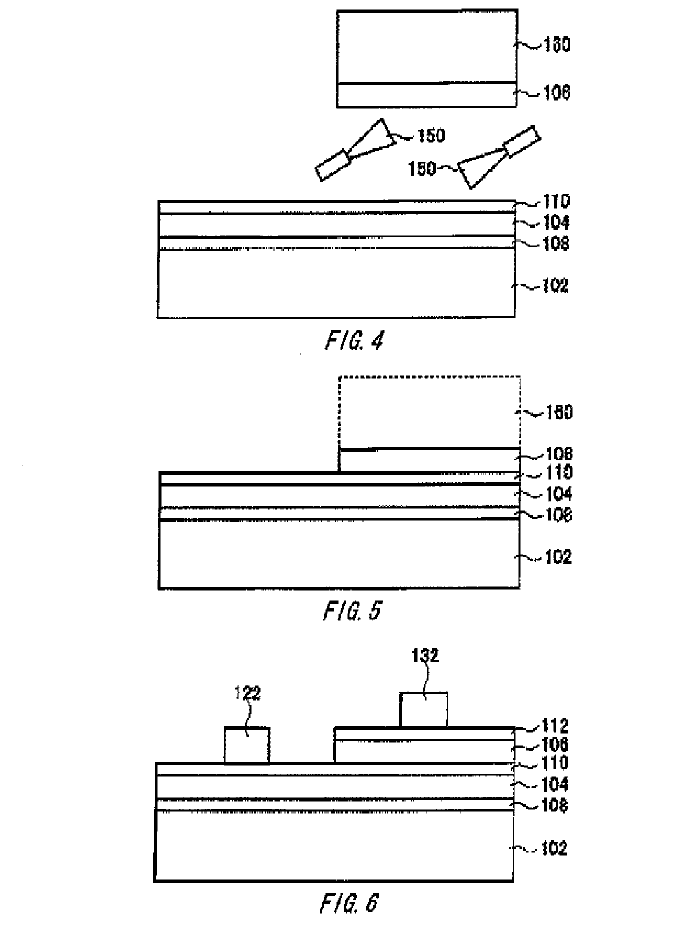

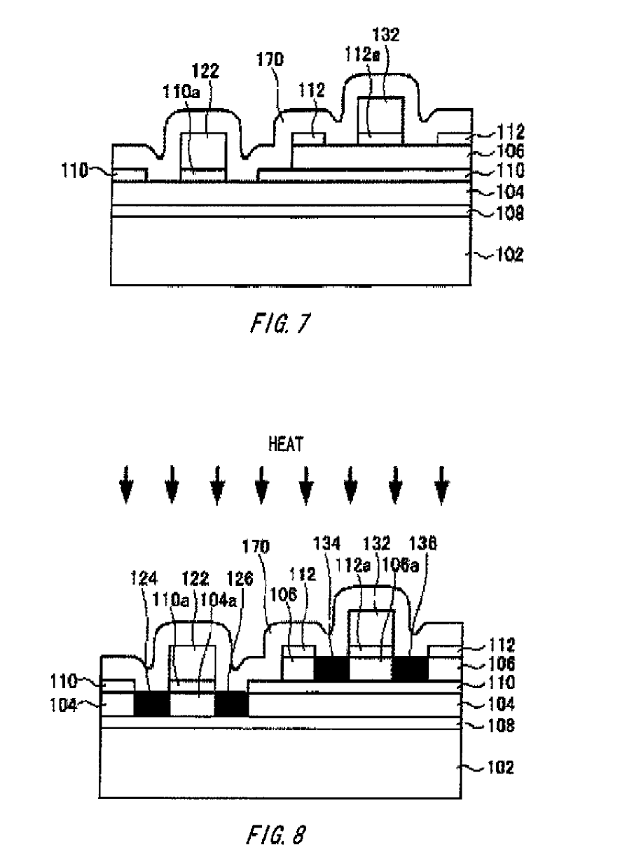

As shown in FIG. 7, apertures that reach the first semiconductor crystal layer 104 are formed through the second separation layer 110 at both sides of the first gate 122, and apertures that reach the second semiconductor crystal layer 106 are formed through insulating layer 112 at both sides of the second gate 132. Here, “both sides of each gate” means both sides of each gate in the horizontal direction. Each of the apertures at both sides of the first gate 122 and the apertures at both sides of the second gate 132 corresponds to a region in which one of the first source 124, the first drain 126, the second source 134, and the second drain 136 will be formed. A metal film 170 made of nickel is formed to be in contact with the first semiconductor crystal layer 104 and the second semiconductor crystal layer 106 exposed on the bottom of these apertures respectively. The metal film 170 may be a cobalt film, or a nickel-cobalt alloy film.

As shown in FIG. 8, the metal film 170 is heated. By heating, the first semiconductor crystal layer 104 reacts with the metal film 170 to form a low-resistance compound having an atom constituting the first semiconductor crystal layer 104 and an atom constituting the metal film 170, thereby forming the first source 124 and the first drain 126. Simultaneously, the second semiconductor crystal layer 106 reacts with the metal film 170 to form a low-resistance compound having an atom constituting the second semiconductor crystal layer 106 and an atom constituting the metal film 170, thereby forming the second source 134 and the second drain 136. When the metal film 170 is a nickel film, a low resistance compound having an atom constituting the first semiconductor crystal layer 104 and a nickel atom is generated as the first source 124 and the first drain 126, and a low resistance compound having an atom constituting the second semiconductor crystal layer 106 and a nickel atom is generated as the second source 134 and the second drain 136. When the metal film 170 is a cobalt film, a low resistance compound having an atom constituting the first semiconductor crystal layer 104 and a cobalt atom is generated as the first source 124 and the first drain 126, and a low resistance compound having an atom constituting the second semiconductor crystal layer 106 and a cobalt atom is generated as the second source 134 and the second drain 136. When the metal film 170 is a nickel-cobalt alloy film, a low resistance compound having an atom constituting the first semiconductor crystal layer 104, a nickel atom and a cobalt atom is generated as the first source 124 and the first drain 126, and a low resistance compound having an atom constituting the second semiconductor crystal layer 106, a nickel atom and a cobalt atom is generated as the second source 134 and the second drain 136. A non-reacted portion of the metal film 170 is removed, thereby producing the semiconductor device 100 as illustrated in FIG. 1.

The heating method for the metal film 170 is preferably RTA (rapid thermal annealing). When the RTA is adopted, the heating temperature can be in the range of 250° C. to 450° C. According to the above-stated method, the first source 124, the first drain 126, the second source 134, and the second drain 136 can be formed by self-aligning them.

According to the above-explained semiconductor device 100 and its production method, the first source 124, the first drain 126, the second source 134, and the second drain 136 can be simultaneously formed by the same process, and so the production process can be simplified. The production cost can be resultantly reduced, and the miniaturization can be employed easily. Moreover, the first source 124, the first drain 126, the second source 134, and the second drain 136 are a low resistance compound having an atom constituting the first semiconductor crystal layer 104 or the second semiconductor crystal layer 106 (i.e., a Group IV atom or Group III-V atoms) and nickel, cobalt, or a nickel-cobalt alloy. The contact potential barrier between these low resistance compounds, and the first semiconductor crystal brier layer 104 and the second semiconductor crystal layer 106 constituting the channel of the semiconductor device 100 is extremely low, specifically 0.1 eV or below. In addition, the contact of each of the first source 124, the first drain 126, the second source 134, and the second drain 136, with respect to its electrode metal becomes an ohmic contact, and the on-current of the first MISFET 120 and the second MISFET 130 can be resultantly increased. In addition, the resistance for each of the first source 124, the first drain 126, the second source 134, and the second drain 136 will be small, and so it becomes unnecessary to lower the channel resistance of the first MISFET 120 and the second MISFET 130, and the concentration of the doping impurity atoms can be reduced. Consequently, the mobility of the carrier in the channel layer can be enhanced.

In the semiconductor device 100 explained above, the base wafer 102 is in contact with the first separation layer 108, and so, if the region of the base wafer 102 in contact with the first separation layer 108 has a conductive property, a voltage can be applied on the region of the base wafer 102 in contact with the first separation layer 108, and the mentioned voltage can be used as a back gate voltage for the first MISFET 120. Moreover in the semiconductor device 100 explained above, the first semiconductor crystal layer 104 is in contact with the second separation layer 110, and so, if the region of the first semiconductor crystal layer 104 in contact with the second separation layer 110 has a conductive property, a voltage can be applied on the region of the first semiconductor crystal layer 104 in contact with the second separation layer 110, and the mentioned voltage can be used as a back gate voltage for the second MISFET 130. These back gate voltages function to increase the on-current for the first MISFET 120 and the second MISFET 130, and to decrease the off-current therefor.

In the semiconductor device 100 explained above, there may be a plurality of second semiconductor crystal layers 106, and each of the plurality of second semiconductor crystal layers 106 may be arranged regularly within a plane parallel to an upper plane of the base wafer 102. In addition, the semiconductor device 100 may include a plurality of first semiconductor crystal layers 104, and each of the plurality of first semiconductor crystal layers 104 may be arranged regularly within a plane parallel to an upper plane of the base wafer 102. Here, the term “regularly” may be defined as a repetition of the same arrangement patterns. In this case, each of the first semiconductor crystal layers 104 may include a single second semiconductor crystal layer 106 or a plurality of second semiconductor crystal layers 106, and each second semiconductor crystal layer 106 may be ranged regularly within a plane parallel to an upper plane of the first semiconductor crystal layer 104. As explained above, by regularly arranging the first semiconductor crystal layers 104 or the second semiconductor crystal layers 106, it becomes possible to enhance the productivity of the semiconductor wafer used for the semiconductor device 100. The regular arrangement of the second semiconductor crystal layers 106 or the first semiconductor crystal layers 104 may be achieved by one of: a method to pattern the second semiconductor crystal layers 106 or the first semiconductor crystal layers 104 in a regular arrangement after forming the second semiconductor crystal layers 106 or the first semiconductor crystal layers 104 by epitaxial growth; a method for forming the second semiconductor crystal layers 106 or the first semiconductor crystal layers 104 in a regular arrangement in advance by selective epitaxial growth; and a method for forming one or both of the second semiconductor crystal layers 106 and the first semiconductor crystal layers 104 on the semiconductor crystal layer forming wafer 160 by epitaxial growth, then separating the one or both of the second semiconductor crystal layers 106 and the first semiconductor crystal layers 104 from the semiconductor crystal layer forming wafer 160, then shaping the one or both of the second semiconductor crystal layers 106 and the first semiconductor crystal layers 104 into a prescribed shape, and then bonding the one or both of the second semiconductor crystal layers 106 and the first semiconductor crystal layers 104 to the base wafer 102 in a regular arrangement. The mentioned arrangement may also be achieved by a combination of a plurality of the methods listed above.

In the aforementioned semiconductor device 100, the first semiconductor crystal layer 104 and the first separation layer 108 are formed on the semiconductor crystal layer forming wafer 140, then the first separation layer 108 is bonded to the base wafer 102, and then the semiconductor crystal layer forming wafer 140 is removed therefrom to form the first semiconductor crystal layer 104 and the first separation layer 108 on the base wafer 102. On the other hand, when forming the first semiconductor crystal layer 104 made of SiGe and the second semiconductor crystal layer 106 made of a Group III-V compound semiconductor crystal the first semiconductor crystal layer 104 and the first separation layer 108 can be formed by an oxidation condense method. Specifically in this method, prior to the formation of the first semiconductor crystal layer 104, the first separation layer 108 made of an insulator is farmed on the base wafer 102 and a SiGe layer is formed on the first separation layer 108, as a starting material of the first semiconductor crystal layer 104. The SiGe layer is heated in an oxidized atmosphere, to oxidize its surface. By oxidizing the SiGe layer, the concentration of the Ge atoms in the SiGe layer will increase, and so a first semiconductor crystal layer 104 having a higher Ge concentration can be obtained.

Alternatively, when forming the first semiconductor crystal layer 104 made of a Group IV semiconductor crystal and the second semiconductor crystal layer 106 made of a Group III-V compound semiconductor crystal, the first semiconductor crystal layer 104 and the first separation layer 108 can be formed using a smart-cut method. Specifically, a first separation layer 108 made of an insulator is formed on the surface of the semiconductor layer material wafer made of a Group IV semiconductor crystal, and cations are injected through the first separation layer 108 to the predetermined separation depth of the semiconductor layer material wafer. Then the semiconductor layer material wafer is bonded to the base wafer 102 so that the surface of the first separation layer 108 will be bonded to the surface of the base wafer 102, and the semiconductor layer material wafer and the base wafer 102 are heated. By this heating process, the cations injected to the predetermined separation depth and the Group IV atoms constituting the semiconductor layer material wafer react to each other, to degenerate the Group IV semiconductor crystal positioned at the predetermined separation depth. By separating the semiconductor layer material wafer from the base wafer 102 in this state, the portion of the Group IV semiconductor crystal positioned between the base wafer 102 and the degenerated portion of the Group IV semiconductor crystal will be detached from the semiconductor layer material wafer. By subjecting this semiconductor layer material attached to the base wafer 102 to an adequate polishing process, the polished semiconductor crystal layer will be the first semiconductor crystal layer 104.

In the aforementioned semiconductor device 100, when the first separation layer 108 is made of a semiconductor crystal having a wider band gap than a band gap of a semiconductor crystal constituting the first semiconductor crystal layer 104, the first separation layer 108 can be formed by epitaxial growth on the base wafer 102, and the first semiconductor crystal layer 104 can be formed by epitaxial growth on the first separation layer 108. Because the first separation layer 108 and the first semiconductor crystal layer 104 can be created sequentially by means of epitaxial growth, the production process can be simplified.

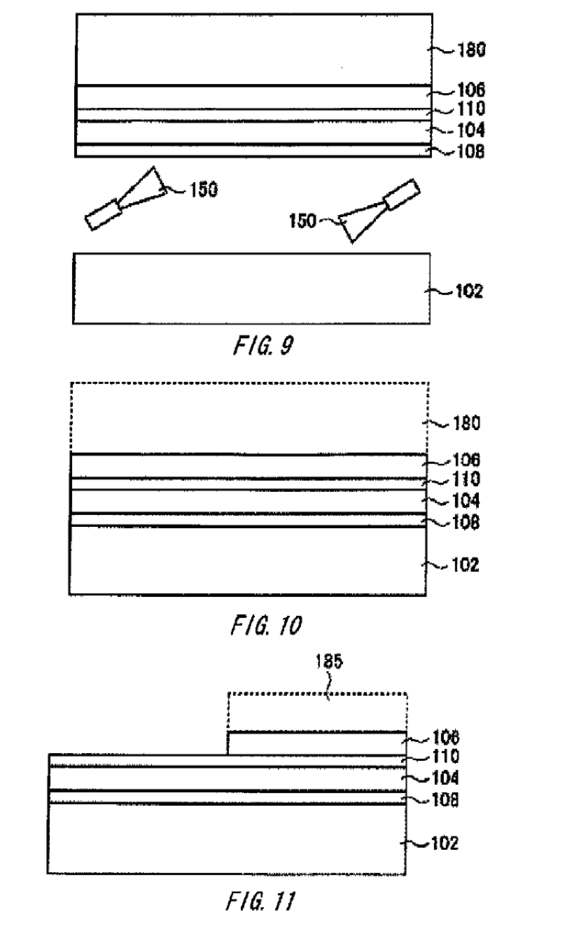

In the aforementioned semiconductor device 100, when the second separation layer 110 is made of a semiconductor crystal having a wider band gap than a bend gap of a semiconductor crystal constituting the second semiconductor crystal layer 106, the second semiconductor crystal layer 106, the second separation layer 110, and the first semiconductor crystal layer 104 can be formed sequentially by means of epitaxial growth. Specifically, as shown in FIG. 9, the second semiconductor crystal layer 106 is formed by epitaxial growth on the semiconductor crystal layer forming wafer 180, the second separation layer 110 is formed by epitaxial growth on the second semiconductor crystal layer 106, and the first semiconductor crystal layer 104 is formed by epitaxial growth on the second separation layer 110. The aforementioned epitaxial growth processes can be employed sequentially. The first separation layer 108 is formed on the first semiconductor crystal layer 104, and the surface of the first separation layer 108 and the surface of the base wafer 102 are activated using a argon beam 150. Subsequently, as shown in FIG. 10, the surface of the first separation layer 108 is bonded to the surface of the base wafer 102, and the semiconductor crystal layer forming wafer 180 is etched away using an HCl solution or the like. Further, as shown in FIG. 11, a mask 185 is used for etching a part of the second semiconductor crystal layer 106, thereby obtaining a semiconductor wafer similar to FIG. 5. According to the above-explained method, because the second semiconductor crystal layer 106, the second separation layer 110, and the first semiconductor crystal layer 104 can be formed sequentially by epitaxial growth, the production process can be simplified.

In the bonding process described above in relation to FIG. 9 and FIG. 10, a first separation layer 108 may be formed on one or both of the base wafer 102 and the first semiconductor crystal layer 104, just as in the case of FIG. 2 and FIG. 3. It is also possible to transfer the first separation layer 108, the first semiconductor crystal layer 104, the second separation layer 110, and the second semiconductor crystal layer 106 to an adequate transfer wafer, and subsequently bond them to the base wafer 102. When the second separation layer 110 is an epitaxially grown crystal, the first semiconductor crystal layer 104, the second separation layer 110, and the second semiconductor crystal layer 106 may be bonded to the base wafer 102, and subsequently the second separation layer 110 may be oxidized to convert it into an amorphous insulating layer. For example when the second separation layer 110 is AlAs or AlInP, the second separation layer 110 can be subjected to a selective oxidation technology to change the second separation layer 110 to an insulating oxide.

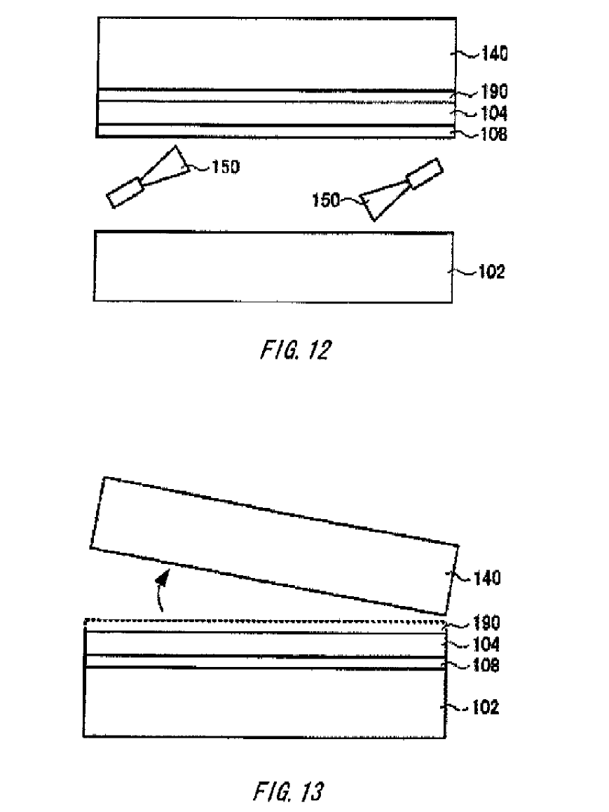

While the semiconductor crystal layer forming wafer is etched away in the bonding process in the production method for the semiconductor device 100 described above, the semiconductor crystal layer forming wafer can be removed by using a crystalline sacrificial layer 190, as shown in FIG. 12. Specifically, prior to forming the first semiconductor crystal layer 104 on the semiconductor crystal layer forming wafer 140, a crystalline sacrificial layer 190 is formed by epitaxial growth on the surface of the semiconductor crystal layer forming wafer 140. Thereafter, the first semiconductor crystal layer 104 and the first separation layer 108 are formed on the surface of the crystalline sacrificial layer 190 by epitaxial growth, and an argon beam 150 is used to activate the surface of the first separation layer 108 and the surface of the base wafer 102. Subsequently, the surface of the first separation layer 108 is bonded to the surface of the base wafer 102, and the crystalline sacrificial layer 190 is removed, as shown in FIG. 13. The first semiconductor crystal layer 104 and the first separation layer 108 provided on the semiconductor crystal layer forming wafer 140 are resultantly separated from the semiconductor crystal layer forming wafer 140. According to this method, a semiconductor crystal layer forming wafer 140 can be recycled, to lead to reduction in production cost.

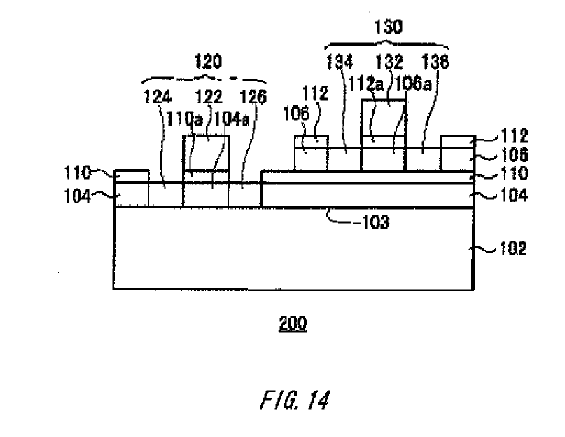

FIG. 14 shows a cross section of a semiconductor device 200. The semiconductor device 200 does not include the first separation layer 108 of the semiconductor device 100, and the first semiconductor crystal layer 104 is provided to be in contact with the base wafer 102. Since the semiconductor device 200 has the same configuration as the semiconductor device 100 except for the lack of the first separation layer 108, the common elements or the like are not explained in the following.

In the semiconductor device 200, the base wafer 102 is in contact with the first semiconductor crystal layer 104 on the bonding plane 103, impurity atoms exhibiting a p-type or n-type conductivity type are contained in an area of the base wafer 102 in the vicinity of the bonding plane 103, and impurity atoms exhibiting a conductivity type different from the conductivity type of impurity atoms contained in the base wafer 102 are contained in an area of the first semiconductor crystal layer 104 in the vicinity of the bonding plane 103. In other words, the semiconductor device 200 includes a pn junction in the vicinity of the bonding plane 103. This indicates that even in a structure without the first separation layer 108, the pn junction formed in the vicinity of the bonding plane 103 can allow the base wafer 102 to be electrically separated from the first semiconductor crystal layer 104, and to allow the first MISFET 120 formed on the first semiconductor crystal layer 104 to be electrically separated from the base wafer 102.

The mentioned separation method that utilizes the pn junction can also be adopted for the separation between the first semiconductor crystal layer 104 and the second semiconductor crystal layer 106. Specifically, in a structure without the second separation layer 110 and whose first semiconductor crystal layer 104 is in contact with the second semiconductor crystal layer 106 via a bonding plane, impurity atoms exhibiting a p-type or n-type conductivity type are contained in an area of the first semiconductor crystal layer 104 in the vicinity of the bonding plan, and impurity atoms exhibiting a conductivity type different from the conductivity type of impurity atoms contained in the first semiconductor crystal layer 104 are contained in an area of the second semiconductor crystal layer 106 in the vicinity of the bonding plane. Consequently, the first semiconductor crystal layer 104 can be electrically separated from the second semiconductor crystal layer 106, and the first MISFET 120 formed on the first semiconductor crystal layer 104 can be electrically separated form the second MISFET 130 formed on the second semiconductor crystal layer 106.

The semiconductor device 200 can also be produced by replacing the processes after the process of forming the first semiconductor crystal layer 104 on the base wafer 102 by epitaxial growth and the second separation layer 110 on the first semiconductor crystal layer 104, with the similar processes as in the case of the semiconductor device 100. Note that the pn junction can be formed by doping the first semiconductor crystal layer 104 with impurity atoms exhibiting a conductivity type different from the conductivity type of impurity atoms contained in the base wafer 102, in the process of making the base wafer 102 contain impurity atoms exhibiting a p-type or n-type conductivity type in the vicinity of the surface of the base wafer 102, and forming the first semiconductor crystal layer 104 by epitaxial growth.

In the structure in which the first semiconductor crystal layer 104 is formed directly on the base wafer 102, when an device isolation is unnecessary, it is not necessary to form the pn junction as a separation structure. In other words, the semiconductor device 200 may have such a structure that does not include any impurity atoms exhibiting a p-type or n-type conductivity type in a area of the base wafer 102 in the vicinity of the bonding plane 103, and does not include any impurity atoms exhibiting a p-type or n-type conductivity type in an area of the first semiconductor crystal layer 104 in the vicinity of the bonding plane 103.

When forming the first semiconductor crystal layer 104 directly on the base wafer 102, an annealing treatment can be employed either after or during the epitaxial growth process. By employing the annealing treatment, the dislocation contained in the first semiconductor crystal layer 104 will be decreased. The epitaxial growth process may be either a method to grow the first semiconductor crystal layer 104 uniformly on the entire surface of the base wafer 102, or a selective growth method that divides the surface of the base wafer 102 minutely using the growth inhibiting layer made of SiO₂, or the like.

The operations, procedures, steps, and stages of each process performed by an apparatus, system, program, and method shown in the claims specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order. In addition, such a phrase as “a first layer is “above” a second layer” includes both cases in which the first layer is provided to be in contact with the upper plane of the second layer, and there is another layer interposed between the lower plane of the rat layer and the upper plane of the second layer. The terms related to directions (e.g., “upper”, “lower”) respectively show relative directions in a semiconductor wafer and a semiconductor device, and should not be interpreted as absolute directions in relation to the outside reference plane such as the ground surface.

While the embodiment(s) of the present invention has (have) been described, the technical scope of the invention is not limited to the above described embodiment(s). It is apparent to persons skilled in the art that various alterations and improvements can be added to the above-described embodiment(s). It is also apparent from the scope of the claims that the embodiments added with such alterations or improvements can be included in the technical scope of the invention.

1. A semiconductor device comprising:
a base wafer;
a first semiconductor crystal layer positioned above the base wafer;
a second semiconductor crystal layer positioned above a partial area of the first semiconductor crystal layer;
a first MISFET having a channel formed in a part of an area of the first semiconductor crystal layer above which the second semiconductor crystal layer does not exist and having a first source and a first drain; and
a second MISFET having a channel formed in a part of the second semiconductor crystal layer and having a second source and a second drain, wherein
the first MISFET is a first-cannel-type MISFET and the second MISFET is a second-channel-type MISFET, the second-channel-type being different from the first-channel-type,
the first source and the first drain are made of a compound having an atom constituting the first semiconductor crystal layer and a nickel atom, a compound having an atom constituting the first semiconductor crystal layer and a cobalt atom, or a compound having an atom constituting the first semiconductor crystal layer, a nickel atom, and a cobalt atom, and
the second source and the second drain are made of a compound having an atom constituting the second semiconductor crystal layer and a nickel atom, a compound having an atom constituting the second semiconductor crystal layer and a cobalt atom, or a compound having an atom constituting the second semiconductor crystal layer, a nickel atom, and a cobalt atom.

2. The semiconductor device according to claim 1, further comprising:
a first separation layer that is positioned between the base wafer and the first semiconductor crystal layer, and electrically separates the base wafer from the first semiconductor crystal layer, and
a second separation layer that is positioned between the first semiconductor crystal layer and the second semiconductor crystal layer, and electrically separates the first semiconductor crystal layer from the second semiconductor crystal layer.

3. The semiconductor device according to claim 1, further comprising:
a second separation layer that is positioned between the first semiconductor crystal layer and the second semiconductor crystal layer, and electrically separates the first semiconductor crystal layer from the second semiconductor crystal layer, wherein
the base wafer is in contact with the first semiconductor crystal layer via a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the first semiconductor crystal layer in the vicinity of the bonding plane.

4. The semiconductor device according to claim 2, wherein
the base wafer is in contact with the first separation layer,
an area of the base wafer that is in contact with the first separation layer is conductive, and
a voltage applied to the area of the base wafer that is in contact with the first separation layer functions as a back gate voltage with respect to the first MISFET.

5. The semiconductor device according to claim 2, wherein
the first semiconductor crystal layer is in contact with the second separation layer,
an area of the first semiconductor crystal layer that is in contact with the second separation layer is conductive, and
a voltage applied to the area of the first semiconductor crystal layer that is in contact with the second separation layer functions as a back gate voltage with respect to the second MISFET.

6. The semiconductor device according to claim 1, wherein
the first semiconductor crystal layer is made of a Group IV semiconductor crystal, and the first MISFET is a P-cannel-type MISFET, and
the second semiconductor crystal layer is made of a Group III-V compound semiconductor crystal, and the second MISFET is an N-channel-type MISFET.

7. The semiconductor device according to claim 1, wherein
the first semiconductor crystal layer is made of a Group III-V compound semiconductor crystal, and the first MISFET is an N-channel-type MISFET, and
the second semiconductor crystal layer is made of a Group IV semiconductor crystal, and the second MISFET is a P-channel-type MISFET.

8. A semiconductor wafer used for the semiconductor device according to claim 1, the semiconductor wafer comprising:
the base wafer, the first semiconductor crystal layer, and the second semiconductor crystal layer, wherein
the first semiconductor crystal layer is positioned above the base wafer, and
the second semiconductor crystal layer is positioned above a part or all of the first semiconductor crystal layer.

9. The semiconductor wafer according to claim 8, further comprising:
a first separation layer that is positioned between the base wafer and the first semiconductor crystal layer, and electrically separates the base wafer from the first semiconductor crystal layer, and
a second separation layer that is positioned between the first semiconductor crystal layer and the second semiconductor crystal layer, and electrically separates the first semiconductor crystal layer from the second semiconductor crystal layer.

10. The semiconductor wafer according to claim 9, wherein
the first separation layer is made of an amorphous insulator.

11. The semiconductor wafer according to claim 9, wherein
the first separation layer is made of a semiconductor crystal having a wider band gap than a bend gap of a semiconductor crystal constituting the first semiconductor crystal layer.

12. The semiconductor wafer according to claim 8, further comprising:
a second separation layer that is positioned between the first semiconductor crystal layer and the second semiconductor crystal layer, and electrically separates the first semiconductor crystal layer from the second semiconductor crystal layer, wherein
the base wafer is in contact with the first semiconductor crystal layer via a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the first semiconductor crystal layer in the vicinity of the bonding plane.

13. The semiconductor wafer according to claim 9, wherein
the second separation layer is made of an amorphous insulator.

14. The semiconductor wafer according to claim 9, wherein
the second separation layer is made of a semiconductor crystal having a wider band gap than a band gap of a semiconductor crystal constituting the second semiconductor crystal layer.

15. The semiconductor wafer according to claim 8, comprising:
a plurality of the second semiconductor crystal layers, wherein
each of the plurality of second semiconductor crystal layers is arranged regularly within a plane parallel to an upper plane of the base wafer.

16. A method for producing the semiconductor wafer according to claim 8, the method comprising:
first semiconductor crystal layer forming of forming the first semiconductor crystal layer above the base wafer; and
second semiconductor crystal layer forming of forming the second semiconductor crystal layer above a partial area of the first semiconductor crystal layer, wherein
the second semiconductor crystal layer forming comprises:
epitaxial growth of forming the second semiconductor crystal layer on a semiconductor crystal layer forming wafer by epitaxial growth;
forming, on the first semiconductor crystal layer, on the second semiconductor crystal layer, or on both of the first semiconductor crystal layer and the second semiconductor crystal layer, a second separation layer that electrically separates the first semiconductor crystal layer from the second semiconductor crystal layer; and
bonding the base wafer including the first semiconductor crystal layer to the semiconductor crystal layer forming wafer so that the second separation layer positioned on the first semiconductor crystal layer will be bonded to the second semiconductor crystal layer, that the second separation layer positioned on the second semiconductor crystal layer will be bonded to the first semiconductor crystal layer, or that the second separation layer positioned on the first semiconductor crystal layer will be bonded to the second separation layer positioned on the second semiconductor crystal layer.

17. The method according to claim 16, for producing the semiconductor wafer, wherein
the first semiconductor crystal layer forming comprises:
epitaxial growth of forming the first semiconductor crystal layer on a semiconductor crystal layer forming wafer by epitaxial growth;
forming, on the base wafer, on the first semiconductor crystal layer, or an both of the base wafer and the first semiconductor crystal layer, a first separation layer that electrically separates the base wafer from the first semiconductor crystal layer; and
bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

18. The method according to claim 16, for producing the semiconductor wafer, wherein
the first semiconductor crystal layer is made of SiGe, and the second semiconductor crystal layer is made of a Group III-V compound semiconductor crystal,
the method comprises, prior to the first semiconductor crystal layer forming, forming a first separation layer made of an insulator on the base wafer, and
the first semiconductor crystal layer forming comprises:
forming a SiGe layer, which serves as a starting material of the first semiconductor crystal layer, on the first separation layer; and
enhancing the concentration of Ge atom in the SiGe layer by beating the SiGe layer in an oxidizing atmosphere to oxidize a surface.

19. The method according to claim 16, for producing the semiconductor wafer, wherein
the first semiconductor crystal layer is made of a Group IV semiconductor crystal, and the second semiconductor crystal layer is made of a Group III-V compound semiconductor crystal, the method comprising:
forming a first separation layer made of an insulator on a surface of a semiconductor layer material wafer made of a Group IV semiconductor crystal;
injecting, via the first separation layer, cations to a predetermined separation depth of the semiconductor layer material wafer;
bonding the semiconductor layer material wafer to the base wafer, so that a surface of the first separation layer will be bonded to a surface of the base wafer;
degenerating the Group IV semiconductor crystal positioned at the predetermined separation depth by heating the semiconductor layer material wafer and the base wafer, and reacting the cations having been injected to the predetermined separation depth and Group IV atoms constituting the semiconductor layer material wafer; and
separating the semiconductor layer material wafer from the base wafer, thereby detaching, from the semiconductor layer material wafer, a portion of the Group IV semiconductor crystal positioned between the base wafer and the degenerated portion of the Group IV semiconductor crystal.

20. The method according to claim 16, for producing the semiconductor wafer, comprising, prior to the first semiconductor crystal layer forming, forming, on the base wafer, a first separation layer made of a semiconductor crystal having a wider band gap than a bend gap of a semiconductor crystal constituting the first semiconductor crystal layer by epitaxial growth, wherein
the first semiconductor crystal layer forming is forming the first semiconductor crystal layer on the first separation layer by epitaxial growth.

21. The method according to claim 16, for producing the semiconductor wafer, wherein
the first semiconductor crystal layer forming is forming the first semiconductor crystal layer on the base wafer by epitaxial growth.

22. The method according to claim 21, for producing the semiconductor wafer, wherein
impurity atoms exhibiting a p-type or n-type conductivity type are contained in the vicinity of a surface of the base wafer, and
in the forming of the first semiconductor crystal layer by epitaxial growth, the first semiconductor crystal layer is doped with impurity atoms exhibiting a conductivity type different from a conductivity type of impurity atoms contained in the base wafer.

23. The method according to claim 14, for producing the semiconductor wafer, comprising:
second semiconductor crystal layer forming of forming the second semiconductor crystal layer on a semiconductor crystal layer forming wafer by epitaxial growth;
second separation layer forming of forming, on the second semiconductor crystal layer, a second separation layer made of a semiconductor crystal having a wider band gap than a bend gap of a semiconductor crystal constituting the second semiconductor crystal layer by epitaxial growth;
first semiconductor crystal layer forming of forming the first semiconductor crystal layer on the second separation layer by epitaxial growth;
forming, on the base wafer, on the first semiconductor crystal layer, or on both of the base wafer and the first semiconductor crystal layer, a first separation layer that electrically separates the base wafer from the first semiconductor crystal layer; and
bonding the base wafer to the semiconductor crystal layer forming wafer so that the first separation layer positioned on the base wafer will be bonded to the first semiconductor crystal layer, that the first separation layer positioned on the first semiconductor crystal layer will be bonded to the base wafer, or that the first separation layer positioned on the base wafer will be bonded to the first separation layer positioned on the first semiconductor crystal layer.

24. The method according to claim 16, for producing the semiconductor wafer, further comprising:
prior to forming a semiconductor crystal layer on the semiconductor crystal layer forming wafer, forming a crystalline sacrificial layer on a surface of the semiconductor crystal layer forming wafer by epitaxial growth; and
separating the semiconductor crystal layer forming wafer from the semiconductor crystal layer having been formed by epitaxial growth on the semiconductor crystal layer forming wafer, by removing the crystalline sacrificial layer, after bonding the base wafer to the semiconductor crystal layer forming wafer.

25. The method according to claim 16, far producing the semiconductor wafer, comprising:
any one of patterning the second semiconductor crystal layers in a regular alignment after having formed the second semiconductor crystal layers by epitaxial growth, or forming the second semiconductor crystal layers in a regular alignment by selective epitaxial growth.

26. A method for producing a semiconductor device, the method comprising:
producing a semiconductor wafer comprising the first semiconductor crystal layer and the second semiconductor crystal layer by using the method according to claim 16 for producing the semiconductor wafer;
forming a gate electrode above each of the first semiconductor crystal layer and the second semiconductor crystal layer, with a gate insulating layer therebetween;
forming a metal film selected from the group consisting of a nickel film, a cobalt film, and a nickel/cobalt alloy film, on a source electrode forming region of the first semiconductor crystal layer, on a drain electrode forming region of the first semiconductor crystal layer, on a source electrode forming region of the second semiconductor crystal layer, and on a drain electrode forming region of the second semiconductor crystal layer;
heating the metal film, thereby forming, in the first semiconductor crystal layer, a first source and a first drain made of a compound having an atom constituting the first semiconductor crystal layer and a nickel atom, a compound having an atom constituting the first semiconductor crystal layer and a cobalt atom, or a compound having an atom constituting the first semiconductor crystal layer, a nickel atom, and a cobalt atom, and forming, in the second semiconductor crystal layer, a second source and a second drain made of a compound having an atom constituting the second semiconductor crystal layer and a nickel atom, a compound having an atom constituting the second semiconductor crystal layer and a cobalt atom, or a compound having an atom constituting the second semiconductor crystal layer, a nickel atom, and a cobalt atom; and
removing a non-reacted portion of the metal film.
